(19) United States
(12) Patent Application Publication
(10) Pub. No.: US 2013/0329155 A1
(43) Pub. Date: Dec. 12, 2013

(54) LIQUID CRYSTAL DISPLAY AND METHOD OF MANUFACTURING THE SAME

(71) Applicant: SAMSUNG DISPLAY CO., LTD., Gyeonggi-do (KR)

(72) Inventors: Chang Hun KWAK, Suwon-si (KR); Min Jung KANG, Incheon (KR); Nu Ree UM, Chungcheongnam-do (KR); Chul HUH, Gyeonggi-do (KR)

(73) Assignee: Samsung Display Co., Ltd., Gyeonggi-do (KR)

(21) Appl. No.: 13/670,851

(22) Filed: Nov. 7, 2012

(30) Foreign Application Priority Data
Jun. 7, 2012 (KR) 10-2012-0061093

(51) Int. Cl. G02F 1/136; G02F 1/1335; H01L 33/00

(52) U.S. Cl. CPC G02F 1/136; H01L 33/0054; G02F 1/133514
USPC 349/43; 438/30; 349/106

(57) ABSTRACT

A liquid crystal display includes a light blocking member on a plurality of color filters, wherein the light blocking member includes a first light blocking member extending along a data line and a second light blocking member extending along a gate line. The first light blocking member is disposed between the plurality of color filters such that a first portion and a second portion of the first light blocking member overlapping an edge of at least one of the color filters respectively have a first width and a second width larger than the first width, and a sub column spacer is formed at the second portion of the first light blocking member.

### CROSS-REFERENCE TO RELATED APPLICATION

This application claims priority to Korean Patent Application No. 10-2012-0061093 filed in the Korean Intellectual Property Office on Jun. 7, 2012, the entire contents of which are incorporated by reference herein.

### TECHNICAL FIELD

Embodiments of the present invention relate to a liquid crystal display and a method of manufacturing the liquid crystal display.

### DISCUSSION OF THE RELATED ART

A liquid crystal display includes two substrates and a liquid crystal layer between the two substrates.

A space in the liquid crystal layers between the two substrates is referred to as a cell gap. To maintain a uniform cell gap between the substrates, a plurality of spacers may be formed on one of the two substrates.

The plurality of spacers include main column spacers for primarily supporting the two substrates and sub column spacers for assisting the main column spacers.

### SUMMARY

Embodiments of the present invention provide a liquid crystal display that includes multi steps formed when light blocking members and spacers are simultaneously formed and a method of manufacturing the liquid crystal display.

An exemplary embodiment of the present invention provides a liquid crystal display including a thin film transistor disposed on a lower substrate, a plurality of color filters disposed on the thin film transistor and spaced apart from each other, a light blocking member disposed on the plurality of color filters, an upper substrate facing the lower substrate, and a liquid crystal layer interposed between the lower substrate and the upper substrate. The light blocking member comprises a first light blocking member extending along a data line and a second light blocking member extending along a gate line. The first light blocking member is disposed between the plurality of color filters. A first portion and a second portion of the first light blocking member overlapping an edge of at least one of the color filters respectively have a first width and a second width larger than the first width, and a sub column spacer is formed at the second portion of the first light blocking member.

A main column spacer may be disposed on the second light blocking member and the main column spacer may support a gap between the upper substrate and the lower substrate.

The sub column spacer may be formed in a region where the first light blocking member crosses the second light blocking member.

At least one of the plurality of color filters may have a stripe shape in a direction in which the data line extends and cross the second light blocking member.

The second light blocking member may be formed to cover the thin film transistor.

The second light blocking member and the main column spacer may be integrally formed.

A height of the sub column spacer may be larger than an average height of the second light blocking member and may be smaller than a height of the main column spacer.

The second light blocking member may be disposed on the first light blocking member.

The liquid crystal display may further include a passivation layer interposed between the first light blocking member and the second light blocking member.

A height of the second portion of the first light blocking member may be larger than a height of the first portion of the first light blocking member.

An exemplary embodiment of the present invention provides a method of manufacturing a liquid crystal display, including forming a thin film transistor on a lower substrate, forming a plurality of color filters on the thin film transistor, wherein the color filters are spaced apart from each other, forming a first light blocking member such that the first light blocking member is disposed between the plurality of color filters, and forming a second light blocking member on the color filters and the first light blocking member, wherein the second light blocking member covers the thin film transistor and comprises a main column spacer, wherein a first portion and a second portion of the first light blocking member overlapping an edge of at least one of the color filters respectively have a first width and a second width larger than the first width, and a sub column spacer is formed at the second portion of the first light blocking member.

The first light blocking member may be formed by a photo lithography method.

The second light blocking member and the main column spacer may be integrally formed by using a two-tone mask.

The method may further include forming a passivation layer between the first light blocking member and the second light blocking member.

The method may further include forming a pixel electrode between the passivation layer and the second light blocking member, wherein the passivation layer may include a contact hole for connecting the pixel electrode with a drain electrode of the thin film transistor, and the main column spacer may be disposed in a portion corresponding to the contact hole.

The sub column spacer may be higher than the second light blocking member, and may be lower than the main column spacer.

According to an embodiment, there is provided a liquid crystal display including a first color filter and a second color filter adjacent to the first color filter, a first light blocking member between the first and second color filters, wherein the first light blocking member includes a first portion and a second portion that overlap an edge of at least one of the first or second color filter, and wherein the first portion has a first width, and the second portion has a second width larger than the first width, and a second light blocking member on the second portion of the first light blocking member, the second light blocking member including a spacer, wherein the second light blocking member is perpendicular or substantially perpendicular to the first light blocking member.

According to the exemplary embodiments of the present invention, multi steps may be formed by forming the light blocking member to overlap the edge of the color filter and then forming the additional light blocking member including the main column spacer.

### BRIEF DESCRIPTION OF THE DRAWINGS

FIG. 1 is a top plan view illustrating a liquid crystal display according to an exemplary embodiment of the present invention.

FIG. 2 is a cross-sectional view taken along line II-II of FIG. 1.

FIG. 3 is a cross-sectional view taken along line of FIG. 1.

FIG. 4 is a top plan view more specifically illustrating the liquid crystal display of FIG. 1.

FIG. 5 is a cross-sectional view taken along line V-V of FIG. 4.

FIGS. 6 and 7 are top plan views illustrating a method of manufacturing a liquid display device according to an embodiment of the present invention.

### DETAILED DESCRIPTION OF THE EMBODIMENTS

Exemplary embodiments of the present invention will be described with reference to the accompanying drawings. However, the present invention is not limited to the exemplary embodiments described herein and may be specified in other forms.

In the drawings, thicknesses of layers and regions may be exaggerated for accuracy. In the following description, when it is said that a layer or substrate is “on” another element, it will be understood that the layer or substrate is positioned either directly on said another element, or on said another element with an element positioned between them. As used herein, the singular forms, “a,” “an” and “the” are intended to include the plural forms as well, unless the context clearly indicates otherwise. Like reference numerals may designate like or similar elements throughout the specification and the drawings.

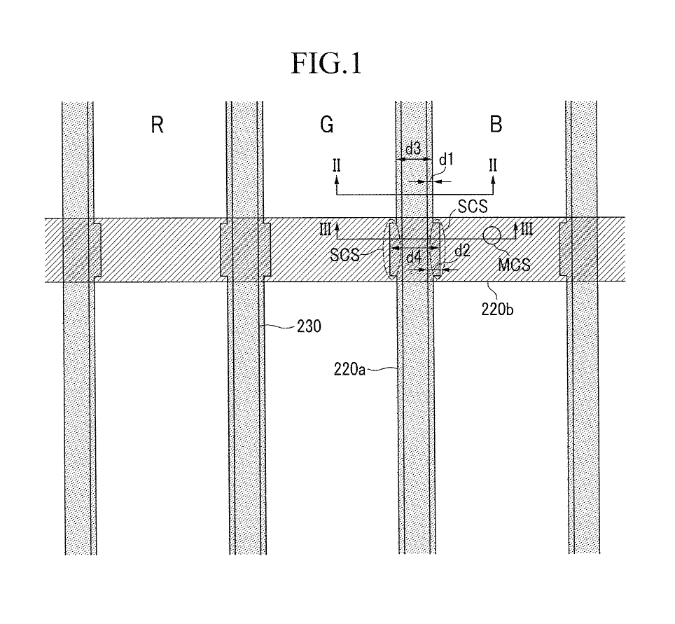

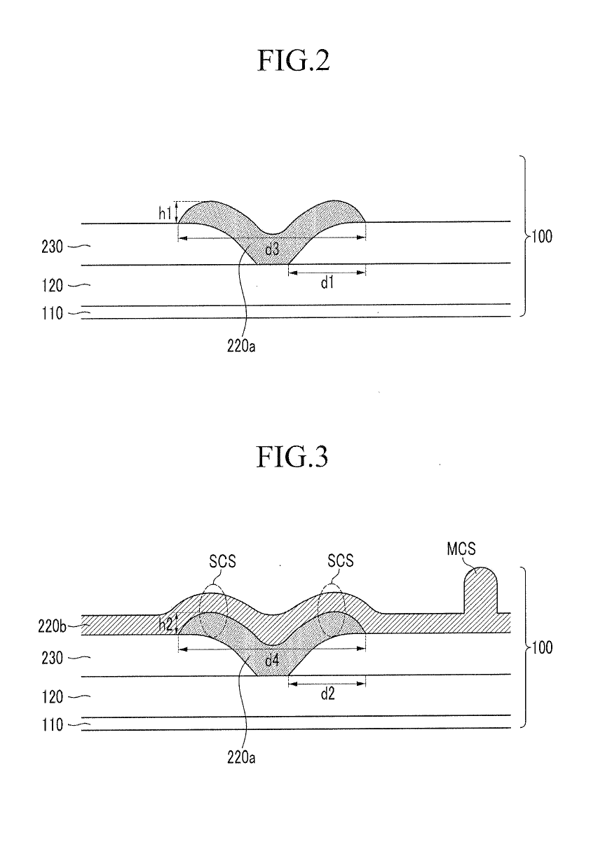

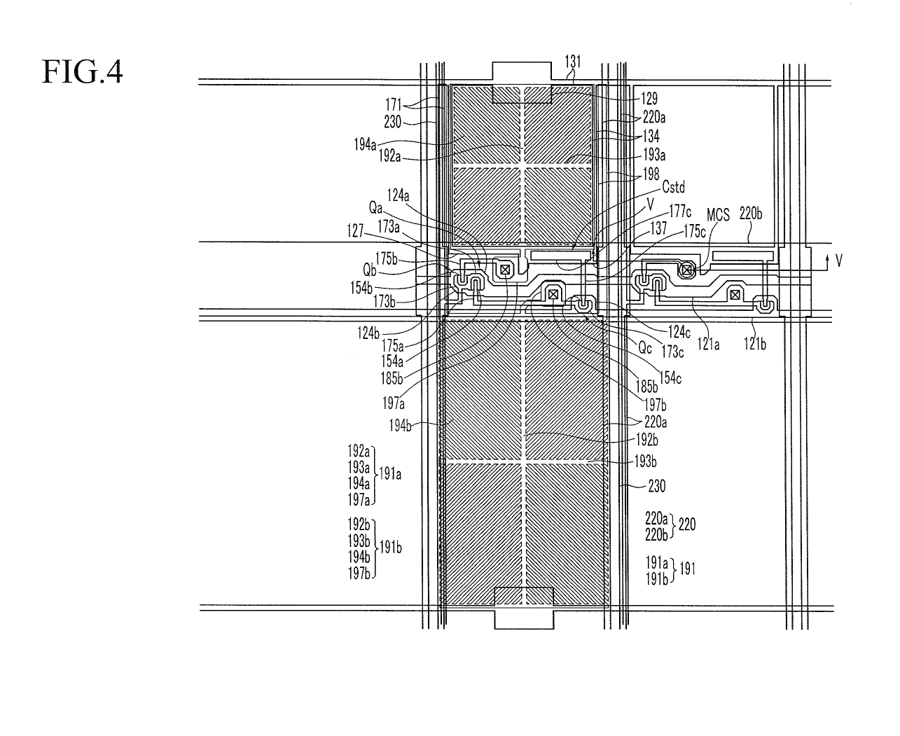

FIG. 1 is a top plan view illustrating a liquid crystal display according to an exemplary embodiment of the present invention. FIG. 2 is a cross-sectional view taken along line II-II of FIG. 1. FIG. 3 is a cross-sectional view taken along line of FIG. 1.

Referring to FIGS. 1 to 3, a film structure 120 including a thin film transistor is formed on a lower substrate 110. The thin film transistor is a switching element and may include three terminals including a control terminal, an input terminal, and an output terminal.

A plurality of color filters 230 are formed on the film structure 120. The plurality of color filters 230 include a red color filter, a green color filter, and a blue color filter which are spaced apart from each other. The plurality of color filters 230 are spaced apart from each other in a horizontal direction. According to an embodiment, the color filters 230 are formed in a stripe form along a vertical direction.

A first light blocking member 220a is formed on the plurality of color filters 230. In an exemplary embodiment, the first light blocking member 220a is disposed between adjacent color filters 230 and overlap edges of the color filters 230.

As illustrated in FIGS. 1 and 2, in an exemplary embodiment, the first light blocking member 220a has a portion of a first width dl, which overlaps an edge of the color filter 230. The first light blocking member 220a extends long in a vertical direction while having a third width d3 that is a width of the first light blocking member 220a. According to an embodiment, the first light blocking member 220a is disposed in a direction in which a data line connected to the thin film transistor extends. In other words, the first light blocking member 220a extends parallel or substantially parallel to the data line.

In an exemplary embodiment, the first light blocking member 220a includes a portion of a second width d2, which overlaps the color filter 230. The second width d2 is larger than the first width dl. The first light blocking member 220a slightly extends in a vertical direction while having a fourth width d4 which is larger than the third width d3. The portion of first light blocking member 220a having the fourth width d4 has a quadrangle shape, but it is not limited thereto, and alternatively, has various shapes, such as as a dumbbell, a circle, or an oval.

Since the first light blocking member 220a is formed between the adjacent color filters 230 and overlaps an edge of the color filter 230, a step as illustrated in FIGS. 2 and 3 is created. A height h2 of a step created at the portion of first light blocking member 220a having the second width d2 and overlapping the color filter 230 is larger than a height hl of a step created at the portion of the first light blocking member 220a having the first width dl and overlapping the color filter 230. As the width of the portion of the first light blocking member 220a, which overlaps the edge of the color filter 230, increases, the height of a created step may increase.

A second light blocking member 220b is disposed to cover the color filter 230 and the first light blocking member 220a. The second light blocking member 220b is aligned in a horizontal direction and crosses the first light blocking member 220a over a portion of the first light blocking member 220a, which protrudes in the horizontal direction. In other words, the second light blocking member 220b overlaps the portion of the first light blocking member 220a which has the width d4.

As illustrated in FIG. 3, since the second light blocking member 220b is disposed over the portion of the first light blocking member 220a, which has the second width d2, a step is also created in the second light blocking member 220b due to the step of the first light blocking member 220a. A sub column spacer SCS having a step of a height larger than an average height of the second light blocking member 220b is formed. As illustrated in FIG. 3, two sub column spacers SCS may be respectively formed on the edges of the adjacent color filters 230. According to an embodiment, when the first light blocking member 220a is formed between the color filters 230 such that the first light blocking member 220a overlaps an edge of one of the adjacent color filters 230, one sub column spacer may be formed at the edge of the color filter 230.

According to an exemplary embodiment, the portion of the first light blocking member 220a, which has the second width d2, overlaps the second light blocking member 220b. Accordingly, when a step is formed, a loss of an aperture ratio is minimized.

A main column spacer MCS is formed on the second light blocking member 220b. According to an embodiment, the main column spacer MCS is formed of the same material as a material of the second light blocking member 220b. According to an embodiment, the main column spacer MCS and the second light blocking member 220b are simultaneously formed by using a two-tone mask.

A step may have a size enough to function as the sub column spacer SCS. A size of the step may be increased by increasing a width of the portion of the first light blocking member 220a that overlaps an edge of the color filter 230.

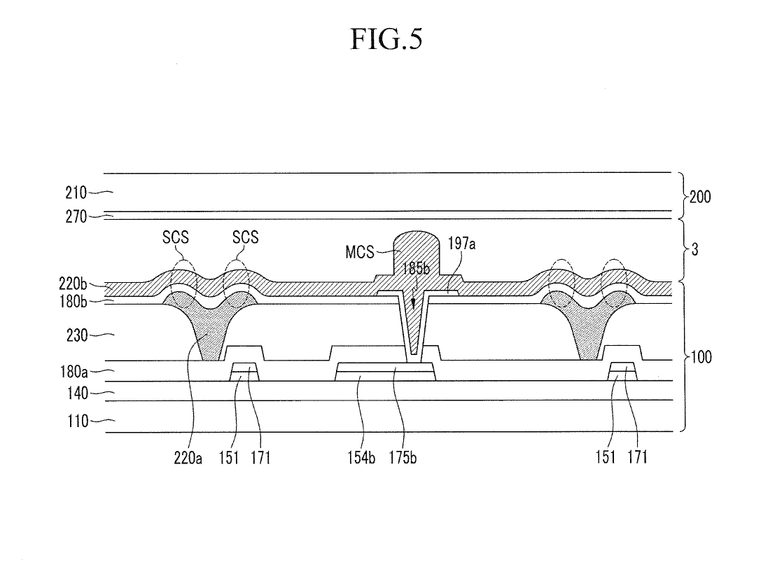

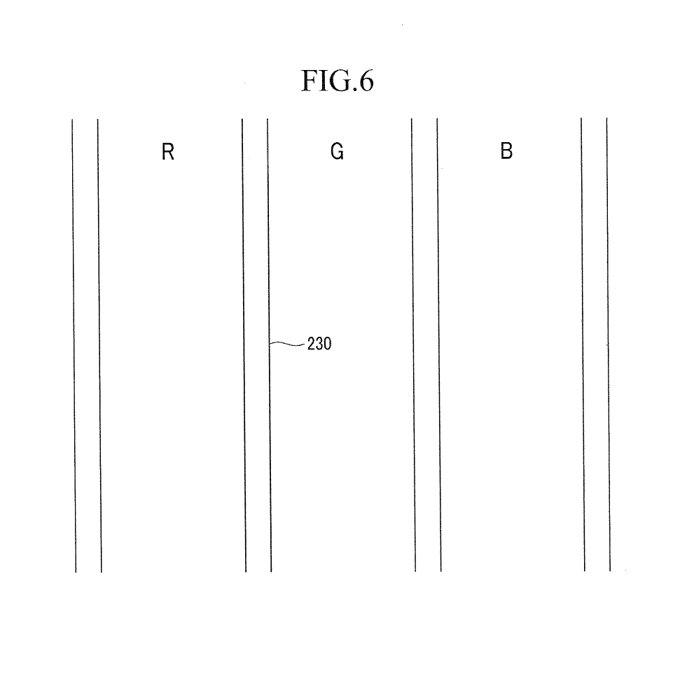

The liquid crystal display of FIG. 1 is described in greater detail with reference to FIGS. 4 and 5.

FIG. 4 is a top plan view more specifically illustrating the liquid crystal display of FIG. 1. FIG. 5 is a cross-sectional view taken along line V-V of FIG. 4.

Referring to FIGS. 4 and 5, the liquid crystal display according to an exemplary embodiment includes a lower panel 100, an upper panel 200 facing the lower panel 100, and a liquid crystal layer 3 interposed between the lower and upper panels.

A plurality of gate lines including a first gate line 121a and a second gate line 121b and a plurality of gate conductors including a plurality of storage electrode lines 131 are formed on a first substrate 110 including pixel regions.

The gate lines 121a and 121b extend in a horizontal direction and transfer a gate signal. The first gate line 121a includes a first gate electrode 124a and a second gate electrode 124b which vertically protrude, and the second gate line 121b includes a vertically protruding third gate electrode 124c. The first gate electrode 124a and the second gate electrode 124b are connected with each other, thus forming one protrusion.

The storage electrode line 131 extends in the horizontal direction and transfers a predetermined voltage, such as a common voltage (Vcom). The storage electrode line 131 includes a vertically protruding storage electrode 129, two vertical parts 134 extending substantially perpendicular to the gate lines 121a and 121b, and a horizontal part 127 for connecting ends of the two vertical parts 134 to each other. The horizontal part 127 includes a downwardly extending capacity electrode 137.

A gate insulating layer 140 is formed on the gate conductors 121a, 121b, and 131.

A plurality of semiconductor stripes 151 that are made of amorphous or crystalline silicon are formed on the gate insulating layer 140. The semiconductor stripes 151 extend in a vertical direction toward the first and second gate electrodes 124a and 124b. The semiconductor stripes 151 include first and second semiconductors 154a and 154b connected to each other and a third semiconductor 154c formed on the third gate electrode 124c.

According to an embodiment, one or more ohmic contacts are formed on the semiconductors 154a, 154b, and 154c. The ohmic contacts are made of silicide or n+ hydrogenated amorphous silicon doped with high-concentration n-type impurities.

A data conductor including a plurality of data lines 171, a plurality of first drain electrodes 175a, a plurality of second drain electrodes 175b, and a plurality of third drain electrode 175c is formed on the ohmic contacts.

The data lines 171 transfer data signals. The data lines cross the gate lines 121a and 121b and extend in a vertical direction. Each data line 171 extends toward the first gate electrode 124a and the second gate electrode 124b and includes a first source electrode 173a and a second source electrode 173b which are connected with each other.

The first drain electrode 175a, the second drain electrode 175b, and the third drain electrode 175c each include a wide end part and an opposite end part shaped as a rod. The rod-shaped opposite end parts of the first drain electrode 175a and the second drain electrode 175b are partially surrounded by the first source electrode 173a and the second source electrode 173b. The wide end part of the first drain electrode 175a extends to form the third drain electrode 175c bent in a “U” shape. A wide end part 177c of the third source electrode 173c overlaps the capacity electrode 137, thus forming a voltage drop capacitor (Cstd). A rod-shaped end part of the third source electrode 173c is partially surrounded by the third drain electrode 175c.

The first gate electrode 124a, the first source electrode 173a, and the first drain electrode 175a form a first thin film transistor Qa together with the first semiconductor 154a. The second gate electrode 124b, the second source electrode 173b, and the second drain electrode 175b form a second thin film transistor Qb together with the second semiconductor 154b. The third gate electrode 124c, the third source electrode 173c, and the third drain electrode 175c form a third thin film transistor Qc together with the third semiconductor 154c.

The semiconductor stripes including the first semiconductor 154a, the second semiconductor 154b, and the third semiconductor 154c have substantially the same flat surface shape as the data conductors 171, 173a, 173b, 173c, 175a, 175b, and 175c and the ohmic contacts, except for channel regions between the source electrodes 173a, 173b, and 173c and the drain electrodes 175a, 175b, and 175c.

The first semiconductor 154a has an exposed part that is not covered by the first source electrode 173a and the first drain electrode 175a between the first source electrode 173a and the first drain electrode 175a. The second semiconductor 154b has an exposed part that is not covered by the second source electrode 173b and the second drain electrode 175b between the second source electrode 173b and the second drain electrode 175b. The third semiconductor 154c has an exposed part that is not covered by the third source electrode 173c and the third drain electrode 175c between the third source electrode 173c and the third drain electrode 175c.

A passivation layer 180a that may be made of an inorganic insulating material, such as silicon nitride or silicon oxide, is formed on the data conductors 171, 173a, 173b, 173c, 175a, 175b, and 175c and the exposed parts of the semiconductors 154a, 154b, and 154c.

The plurality of color filters 230 are formed on the passivation layer 180a. The plurality of color filters 230 include a red color filter, a green color filter, and a blue color filter which are spaced apart from each other. The plurality of color filters 230 are spaced apart from each other in a horizontal direction, and according to an embodiment, may be formed in a stripe shape in a vertical direction.

The first light blocking member 220a is disposed between the plurality of color filters 230. The first light blocking member 220a overlaps an edge of an adjacent color filter 230. Since the first light blocking member 220a is formed between the color filters 230 and covers the edge of the color filter 230, a step is created as illustrated in FIG. 5.

The first light blocking member 220a extends long in a vertical direction and protrudes from a part adjacent to the thin film transistor including the gate lines 121a and 121b. A width of a portion of the first light blocking member 220a overlapping the edge of the color filter 230 is increased by the protruding shape. A height of the step may increase as the width of the portion of the first light blocking member 220a overlapping the edge of the color filter 230 increases.

A second passivation layer 180b is disposed on the first light blocking member 220a and the plurality of color filters 230. According to an embodiment, the second passivation layer 180b is formed as an organic layer or an inorganic layer. Alternatively, the second passivation layer 180b is omitted.

A pixel electrode 191 including a first sub pixel electrode 191a and a second sub pixel electrode 191b is formed on the second passivation layer 180b. The first sub pixel electrode 191a and the second sub pixel electrode 191b are separated from each other, with the first gate line 121a and the second gate line 121b disposed between the first and second sub pixel electrodes 191a and 191b, and are respectively formed at an upper side and a lower side to be adjacent to each other in a column direction. A height of the second sub pixel electrode 191b is more than a height of the first sub pixel electrode 191a. For example, according to an embodiment, the height of the second sub pixel electrode 191b may be about 1 to about 3 times of the height of the first sub pixel electrode 191a.

An overall shape of each of the first sub pixel electrode 191a and the second sub pixel electrode 191b is a quadrangle, and the first sub pixel electrode 191a and the second sub pixel electrode 191b respectively include cross-shaped stem parts including horizontal stem parts 193a and 193b, respectively, and vertical stem parts 192a and 192b, respectively. The vertical stern parts 192a and 192b cross the horizontal stem parts 193a and 193b. The first sub pixel electrode 191a and the second sub pixel electrode 191b respectively includes a plurality of fine branch parts 194a and a plurality of fine branch parts 194b. The first sub pixel electrode 191a includes a protrusion 197a at a lower side, and the second sub pixel electrode 191b includes a protrusion 197b at an upper side.

The pixel electrode 191 is divided into four sub regions by the horizontal stern parts 193a and 193b and the vertical stern parts 192a and 192b. The fine branch parts 194a and 194b slantingly extend from the horizontal stem parts 193a and 193b and the vertical stem parts 192a and 192b. An angle between an extension direction of the fine branch parts 194a and 194b and the gate lines 121a and 121b or the horizontal stem parts 193a and 193b is approximately 45° or approximately 135°. According to an embodiment, the fine branch parts 194a and 194b in the two adjacent sub regions are orthogonal or substantially orthogonal to each other.

According to an exemplary embodiment, the first sub pixel electrode 191a further includes an outside stem part enclosing an outside, and the second sub pixel electrode 191b further includes horizontal parts disposed at an upper side and a lower side and vertical parts 198 disposed at left and right sides of the first sub pixel electrode 191a. The vertical parts 198 may prevent a capacitive coupling, between the data line 171 and the first sub pixel electrode 191a. According to an embodiment, the vertical part 198 is omitted.

A plurality of first contact holes 185a and a plurality of second contact holes 185b, through which the wide end of the first drain electrode 175a and the wide end of the second drain electrode 175b, respectively, are exposed, are formed on the first passivation layer 180a, the color filter 230, and the second passivation layer 180b. The first contact hole 185a connects the second sub pixel electrode 191b to the third drain electrode 175c, and the second contact hole 185b connects the first sub pixel electrode 191a to the second drain electrode 175b.

The second light blocking member 220b is disposed on the pixel electrode 191 and the second passivation layer 180b. The second light blocking member 220b is aligned in a horizontal direction and crosses the first light blocking member 220a. According to an exemplary embodiment, the second light blocking member 220b overlaps the first light blocking member 220a over a portion of the first light blocking member 220a which overlaps a relatively larger area of the edge of the color filter 230. The portion of the first light blocking member 220a which overlaps a relatively more area of the edge of the color filter 230 refers to a part of the first light blocking member 220a protruding in a direction perpendicular or substantially perpendicular to a direction in which the first light blocking member 220a extends.

As illustrated in FIGS. 4 and 5, the second light blocking member 220b overlaps the protruding part of first light blocking member 220a, so that a step is created in the second light blocking member 220b by the step of the first light blocking member 220a. A sub column spacer SCS having a step having a height larger than an average height of the second light blocking member 220b is formed. As illustrated in FIG. 5, the two sub column spacers SCS may be formed about a space between the adjacent color filters 230. However, the embodiments of the present invention are not limited thereto. For example, according to an embodiment, when the first light blocking member 220a is formed around the space between the adjacent color filters 230 to overlap an edge of only one of the color filters 230, one sub column spacer SCS may be formed about the space between the color filters 230.

According to an embodiment, the protruding part of the first light blocking member 220a is formed to overlap the second light blocking member 220b to form the step while minimizing a loss of an aperture ratio.

The main column spacer MCS is disposed on the second light blocking member 220b. According to an embodiment, the main column spacer MCS is formed of the same material as a material of the second light blocking member 220b. According to an embodiment, the main column spacer MCS and the second light blocking member 220b are simultaneously formed by using a two-tone mask. The main column spacer MCS functions as a spacer that supports a space between the upper panel 200 and the lower panel 100. The sub column spacer SCS functions as an assistant spacer for supporting the upper panel 200 and the lower panel 100 by assisting the main column spacer MCS.

According to an exemplary embodiment, the main column spacer MCS is disposed at a position corresponding to the first contact hole 185a or the second contact hole 185b, but it is not limited thereby. Alternatively, the main column spacer MCS is disposed on a region of the second blocking member, which does not correspond to the contact hole 185a or 185b.

The common electrode 270 is formed on an upper substrate 210. According to an embodiment, an upper alignment layer is formed on the common electrode 270. The common electrode 270 transfers a common voltage.

The liquid crystal layer 3 has negative dielectric anisotropy, and the liquid crystal molecules of the liquid crystal layer 3 are aligned such that long axes thereof are perpendicular or substantially perpendicular to the surfaces of the two display panels 100 and 200 when no electric field is generated between the panels 100 and 200. The liquid crystal layer 3 includes an alignment supplement agent containing reactive mesogen, so that the liquid crystal molecules may have a line inclination such that the long axes thereof are approximately parallel to a lengthwise direction of the fine branch parts 194a and 194b of the pixel electrode 191. According to an embodiment, the alignment supplement agent is included in an alignment layer, but not in the liquid crystal layer.

The structure of the thin film transistor described with reference to FIGS. 4 and 5 is merely an exemplary embodiment, and according to embodiments, the layer structure including the structure of the thin film transistor may be modified in various forms.

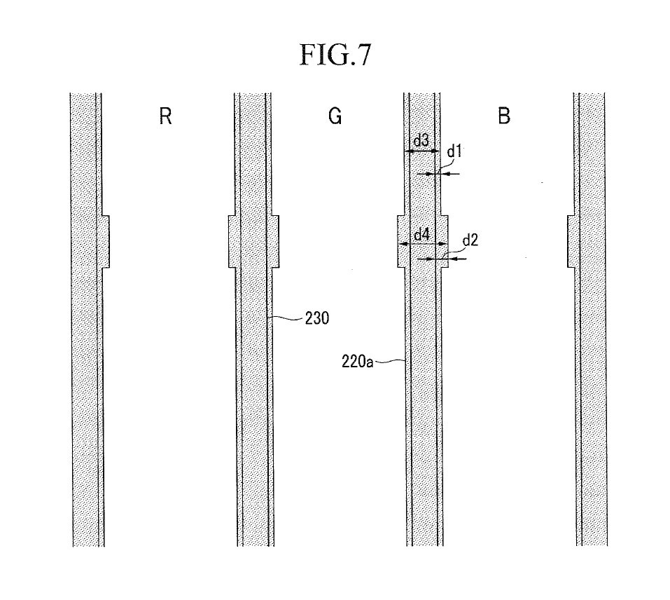

Hereinafter, a method of manufacturing a liquid crystal display according to an exemplary embodiment of the present invention is described with reference to FIGS. 6 and 7.

FIGS. 6 and 7 are top plan views illustrating a method of manufacturing a liquid crystal display according to an exemplary embodiment of the present invention. Referring to FIG. 6, the plurality of color filters 230 are spaced apart from each other. The plurality of color filters 230 are formed such that the red color filter R, the green color filter G, and the blue color filter B are sequentially repeated. The plurality of color filters 230 are spaced apart from each other in a horizontal direction. According to an embodiment, the plurality of color filters 230 are arranged in a stripe form in a vertical direction.

According to an embodiment, the structure including the thin film transistor described in connection with FIGS. 4 and 5 is formed on the lower substrate 110, and the color filters 230 are formed on the thin film transistor.

According to an embodiment, the color filters 230 are formed using a photolithography process, or an inkjet method. However, the embodiments of the present invention are not limited thereto.

Referring to FIG. 7, the first light blocking member 220a is formed along a space between adjacent color filters 230. The first light blocking member 220a is formed long in a direction in which the color filters 230 extend. The first light blocking member 220a has a third width d3 for the most part and a fourth width d4 larger than the third width d3 in a predetermined part. According to an embodiment, the portion of the first light blocking member 220a having the fourth width d4 is formed to overlap the second light blocking member 220b while the first light blocking member crosses the second light blocking member 220b.

According to an embodiment, the first light blocking member 220a is formed using the photo lithography process. The portion of the first light blocking member 220a having the fourth width d4 protrudes by a second width d2 and overlaps the edge of the color filter 230. The second width d2 is larger than a first width d1 by which a portion of the first light blocking member 220 having the third width d3 overlaps the edge of the color filter 230. According to an embodiment, as long as the second width d2 is larger than the first width d1, it is not necessary for the fourth width d4 to be larger than the third width d3. The height of the step may be adjusted by adjusting the second width d2, e.g., by having the second width d2 larger than the first width d1.

Then, the second light blocking member 220b is formed along the horizontal direction to cover the thin film transistor, thereby forming the lower panel illustrated in FIG. 1.

Since the second light blocking member 220b overlaps the portion of the first light blocking member 220a having the second width d2, a step is created in the second light blocking member 220b by the step created in the first light blocking member 220a.

According to an embodiment, to simultaneously form the main column spacer MCS and the second light blocking member 220b, a two-tone mask is used. Accordingly, the second light blocking member 220b and the main column spacer MCS may be simultaneously formed at different heights. Since the second light blocking member 220b and the MCS are formed using the two-tone mask, the second light blocking member 220b and the MCS may be integrally formed of the same or substantially the same material. According to an embodiment, the two-tone mask includes a half-tone mask or a silk mask.

For example, according to an embodiment, when a negative photo resist is used to form the second light blocking member 220b, a region where the main column spacer MCS is to be formed is set to have 100% light transmittance, and another region may be set to have about 30% light transmittance. The main column spacer MCS is formed in a region which is not etched after the photo process, and the second light blocking member 220b having a height smaller than a height of the main column spacer MCS is formed on another region which is partially etched. An SCS having a height larger than an average height of the second light blocking member 220b is formed on the region of second light blocking member 220b where the step of the first light blocking member 220a is formed.

Then, the upper panel including the common electrode is formed on the upper substrate, and the liquid crystal layer is formed by bonding the upper panel with the lower panel, so that the liquid crystal display including the light blocking member having the multi steps and the column spacer may be formed.

While the embodiments of the invention have been described, it is to be understood that the invention is not limited to the disclosed embodiments, but, on the contrary, is intended to cover various modifications and equivalent arrangements included within the spirit and scope of the appended claims.

What is claimed is:

1. A liquid crystal display comprising:
a thin film transistor disposed on a lower substrate;
a plurality of color filters disposed on the thin film transistor, wherein the plurality of color filters are spaced apart from each other;
a light blocking member disposed on the plurality of color filters;
an upper substrate facing the lower substrate; and
a liquid crystal layer interposed between the lower substrate and the upper substrate,
wherein the light blocking member comprises a first light blocking member extending along a data line and a second light blocking member extending along a gate line, wherein
the first light blocking member is disposed between the plurality of color filters, and wherein
a first portion and a second portion of the first light blocking member overlapping an edge of at least one of the color filters respectively have a first width and a second width larger than the first width, and a sub column spacer is formed at the second portion of the first light blocking member.

2. The liquid crystal display of claim 1, wherein a main column spacer is disposed on the second light blocking member, and wherein the main column spacer is sized and dimensioned to support a gap between the upper substrate and the lower substrate.

3. The liquid crystal display of claim 2, wherein the sub column spacer is formed in a region where the first light blocking member crosses the second light blocking member.

4. The liquid crystal display of claim 3, wherein at least one of the plurality of color filters has a stripe shape in a direction in which the data line extends and crosses the second light blocking member.

5. The liquid crystal display of claim 4, wherein the second light blocking member is formed to cover the thin film transistor.

6. The liquid crystal display of claim 5, wherein the second light blocking member and the main column spacer are integrally formed.

7. The liquid crystal display of claim 6, wherein a height of the sub column spacer is larger than an average height of the second light blocking member and is smaller than a height of the main column spacer.

8. The liquid crystal display of claim 1, wherein the second light blocking member is disposed on the first light blocking member.

9. The liquid crystal display of claim 8, further comprising a passivation layer interposed between the first light blocking member and the second light blocking member.

10. The liquid crystal display of claim 1, wherein a height of the second portion of the first light blocking member is larger than a height of the first portion of the first light blocking member.

11. A method of manufacturing a liquid crystal display, the method comprising:
forming a thin film transistor on a lower substrate;
forming a plurality of color filters on the thin film transistor, wherein the color filters are spaced apart from each other;
forming a first light blocking member such that the first light blocking member is disposed between the plurality of color filters; and
forming a second light blocking member on the color filters and the first light blocking member, wherein the second light blocking member covers the thin film transistor and comprises a main column spacer,
wherein a first portion and a second portion of the first light blocking member overlapping an edge of at least one of the color filters respectively have a first width and a second width larger than the first width, and a sub column spacer is formed at the second portion of the first light blocking member.

12. The method of claim 11, wherein the sub column spacer is formed in a region where the first light blocking member crosses the second light blocking member.

13. The method of claim 12, wherein at least one of the plurality of color filters has a stripe shape in a direction in which a data line extends and crosses the second light blocking member.

14. The method of claim 13, wherein the first light blocking member is formed to extend along the data line, and the second light blocking member is formed to extend along a gate line.

15. The method of claim 11, wherein a height of the second portion of the first light blocking member is larger than a height of the first portion of the first light blocking member.

16. The method of claim 15, wherein the first light blocking member is formed by a photo lithography method.

17. The method of claim 16, wherein the second light blocking member and the main column spacer are integrally formed by using a two-tone mask.

18. The method of claim 11, further comprising forming a passivation layer between the first light blocking member and the second light blocking member.

19. The method of claim 18, further comprising forming a pixel electrode between the passivation layer and the second light blocking member,
wherein the passivation layer includes a contact hole that connects the pixel electrode with a drain electrode of the thin film transistor, and wherein the main column spacer is disposed in a portion corresponding to the contact hole.

20. The method of claim 11, wherein the sub column spacer is higher than the second light blocking member and is lower than the main column spacer.

21. A liquid crystal display comprising:
a first color filter and a second color filter adjacent to the first color filter;
a first light blocking member between the first and second color filters, wherein the first light blocking member includes a first portion and a second portion that overlap an edge of at least one of the first or second color filter, and wherein the first portion has a first width, and the second portion has a second width larger than the first width; and
a second light blocking member on the second portion of the first light blocking member, the second light blocking member including a spacer, wherein the second light blocking member is perpendicular or substantially perpendicular to the first light blocking member.
